(19) United States
(12) Patent Application Publication
(10) Pub. No.: US 2024/0118628 A1
(43) Pub. Date: Apr. 11, 2024

(54) SEMICONDUCTOR PATTERN FOR A PATTERNING PROCESS, AND METHOD AND SYSTEM FOR OVERLAY CONTROL USING THE SEMICONDUCTOR PATTERN

(71) Applicant: Prosemi Co., Ltd., Tainan City (TW)

(72) Inventor: Chen-Kun WANG, Tainan City (TW)

(21) Appl. No.: 18/482,413

(22) Filed: Oct. 6, 2023

(30) Foreign Application Priority Data
Oct. 7, 2022 (TW) 111138284

(51) Int. Cl. G03F 7/00; H01L 21/027

(52) U.S. Cl. CPC G03F 7/70633; G03F 7/70625; G03F 7/7065; H01L 21/0274

(57) ABSTRACT

A semiconductor pattern includes a first pattern section and a second pattern section. Each of the first pattern section and the second pattern section includes a plurality of irregularly arranged first unit images and at least one set of second unit images disposed outside the first unit images. Each set of second unit images includes a plurality of second unit images that are equidistantly spaced apart from one another. The sets of second unit images of the first pattern section and the second pattern section form an outer part. The outer part has a plurality of sides, and each side is formed by one set of second unit images of the first pattern section and a corresponding set of second unit images of the second pattern section.

### CROSS-REFERENCE TO RELATED APPLICATION

This application claims priority to Taiwanese Invention Patent Application No. 111138284 filed on Oct. 7, 2022, the entire disclosure of which is incorporated by reference herein.

### FIELD

The disclosure relates to a semiconductor fabrication process for manufacturing a semiconductor device, and more particularly to a semiconductor pattern for a patterning process, and a method and a system for performing overlay control using the semiconductor pattern.

### BACKGROUND

As the field of semiconductor fabrication progresses, the structure of semiconductor devices has become progressively more complicated, multi-layered, and dense. During the manufacturing of the semiconductor devices (in which a plurality of layers, each having a specific pattern, are laid in order), lithography is typically used to transfer one or more two-dimensional patterns onto a layer (e.g., a substrate), so as to form a patterned layer. In newer processes, a pitch associated with patterns may be about tens of nanometers to a few micrometers.

As the patterns become smaller in scale and higher in density, and more patterned layers are employed in forming the semiconductor devices, when one of the layers is misaligned with a previous one of the layers, one or more layers that are to be formed after the one of the layers may be adversely affected, which may cause the resultant semiconductor device to have malfunctions occurring within adjacent patterned layers, such as connection failures and/or short circuits. Accordingly, overlay control, which involves the control of layer-to-layer alignment of semiconductor devices, has become an important issue. In current semiconductor manufacturing processes that involve photolithography, the overlay control may involve defining one or more overlay patterns on multiple layers of the semiconductor device (e.g., on one specific patterned layer, and a prior layer that is formed prior to the specific patterned layer and a subsequent layer that is formed after the specific patterned layer), and calculating a displacement of the overlay pattern(s) (also known as an overlay error) on different layers so as to determine whether the alignment of the patterned layers is accurate. In the case where an overlay error is detected, a compensation for the overlay error may be needed for the manufacturing process of the next batch of semiconductor devices. Specifically, prior to implementation of a manufacturing process for the next batch, a number of process parameters associated with the manufacturing process may be adjusted to compensate for the overlay error (such that the overlay error can be reduced or eliminated for the subsequent manufacturing process).

In practice, the two-dimensional pattern formed on the substrate may involve irregular arrangements of elements such as trenches, vias (also known as through holes), wires or combinations thereof. An overlay pattern that involves regular arrangements of those elements may be insufficient to serve as a reference to determine whether the two-dimensional pattern is aligned accurately.

### SUMMARY

Therefore, one object of the disclosure is to provide a semiconductor pattern used for a semiconductor fabrication process.

According to one embodiment of the disclosure, the semiconductor pattern includes:
a first pattern section including a plurality of first unit images and at least one set of second unit images, the plurality of first unit images being disposed irregularly, the at least one set of second unit images being disposed outside of the plurality of first unit images, each of the at least one set of second unit images including a plurality of second unit images that are equidistantly spaced apart from one another by a distance equaling a first pitch; and
a second pattern section including a plurality of first unit images and at least one set of second unit images, the plurality of first unit images being disposed irregularly, the at least one set of second unit images being disposed outside of the plurality of first unit images, each of the at least one set of second unit images including a plurality of second unit images that are equidistantly spaced apart from one another by a distance equaling a second pitch, the first pitch being identical to the second pitch.

The first pattern section and the second pattern section are to be formed on a substrate using a first sub-process and a second sub-process of the semiconductor fabrication process, respectively. The first unit images of the first pattern section and the first unit images of the second pattern section cooperatively form an inner part, and the at least one set of second unit images of the first pattern section and the at least one set of second unit images of the second pattern section cooperatively form an outer part. The outer part has at least one side, each of which is formed by one of the at least one set of second unit images of the first pattern section and a corresponding one of the at least one set of second unit images of the second pattern section.

Another object of the disclosure is to provide a method overlay control that utilizes the above-mentioned semiconductor pattern.

According to one embodiment of the disclosure, the method for overlay control includes:
obtaining data of an image of a selected area that includes the above-mentioned semiconductor pattern;
generating an overlay error dataset based on the semiconductor pattern and a reference dataset, the reference dataset including a reference image that corresponds with the semiconductor pattern, or a plurality of reference parameters associated with the semiconductor pattern; and
generating, based on the overlay error dataset, a calibrating parameter dataset that indicates one or more changes to be made on at least one process parameter that is to be used in the semiconductor fabrication process for manufacturing a next batch of semiconductor devices.

Another object of the disclosure is to provide a system for overlay control that is configured to perform the above-mentioned method.

According to one embodiment of the disclosure, the system includes:
a data obtaining unit that obtains data of an image of a selected area that includes the above-mentioned semiconductor pattern;
an alignment checking unit that generates an overlay error dataset based on the semiconductor pattern and a reference dataset; and
a computing unit that generates, based on the overlay error dataset, a calibrating parameter dataset that indicates one or more changes to be made on at least one process parameter that is to be used in the semiconductor fabrication process for manufacturing a next batch of semiconductor devices.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a block diagram illustrating components of a system for overlay control according to one embodiment of the disclosure

FIG. 2 is a flow chart illustrating steps of a method for overlay control according to one embodiment of the disclosure.

FIGS. 3 and 4 illustrate a first pattern section and a second pattern section of a calibrating pattern, respectively, according to one embodiment of the disclosure.

FIG. 5 illustrates an exemplary selected area, which depicts an image of a calibrating pattern according to one embodiment of the disclosure.

FIG. 6 illustrates an exemplary reference image (shown in dashed lines) being superposed on the calibrating pattern.

FIG. 7 illustrates an exemplary calibrating pattern according to one embodiment of the disclosure.

FIG. 8 illustrates a manner in which relative displacements for a plurality of unit images of the calibrating pattern are obtained.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

Throughout the disclosure, the term “coupled to” or “connected to” may refer to a direct connection among a plurality of electrical apparatus/devices/equipment via an electrically conductive material (e.g., an electrical wire), or an indirect connection between two electrical apparatus/devices/equipment via another one or more apparatus/devices/equipment, or wireless communication.

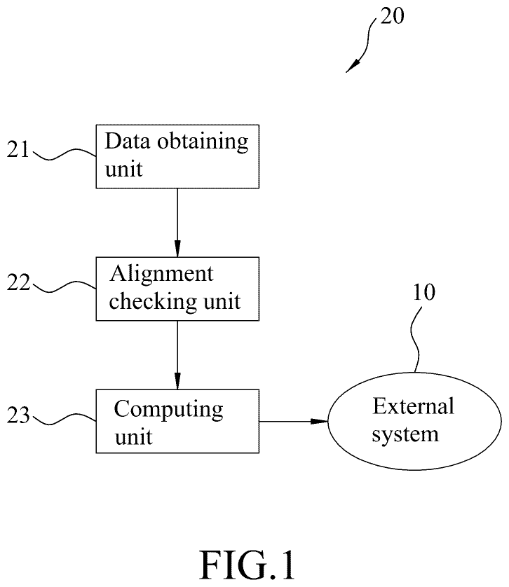

FIG. 1 is a block diagram illustrating components of a system 20 for overlay control according to one embodiment of the disclosure. In this embodiment, the system 20 may be embodied based on a graphic data system (GDS), an open artwork system interchange system (OASIS) program, a computer aided design (CAD) program or an electronic design automation (EDA) program, a manufacturing electron beam exposure system (MEBES), or other systems currently available. The system 20 includes a data obtaining unit 21, an alignment checking unit 22, and a computing unit 23.

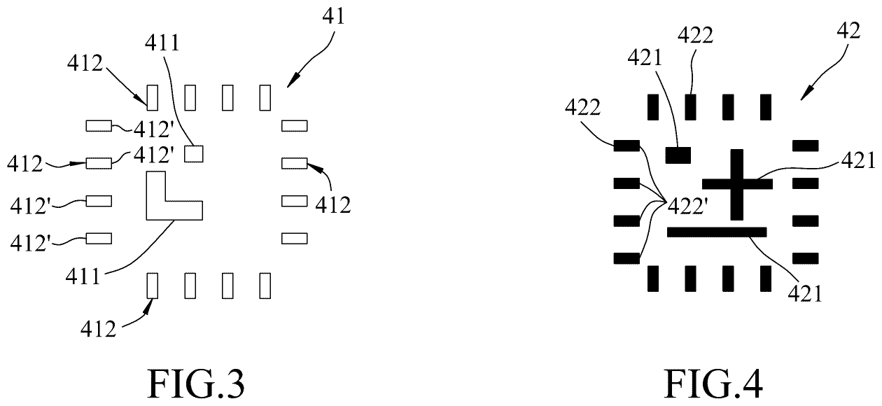

The data obtaining unit 21 may be embodied using a stepper, a scanner, a diffractometer, an electron microscope, an optical microscope or other optical imaging equipment, and is capable of obtaining data of an image of a selected area of a semiconductor pattern (see FIG. 3). In this embodiment, the semiconductor pattern is an image of a fabricated semiconductor device obtained using a stepper, a scanner, a diffractometer, an electron microscope, an optical microscope or other optical imaging equipment.

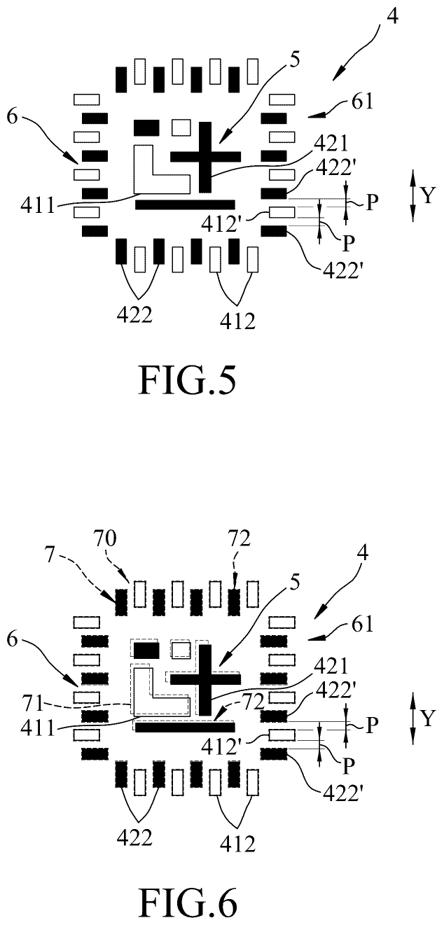

The data obtaining unit 21 is capable of obtaining data of an image of a selected area 40 of a semiconductor pattern (see FIG. 5). In this embodiment, the semiconductor pattern is an image of a fabricated semiconductor device obtained using a stepper, a scanner, a diffractometer, an electron microscope, an optical microscope or other optical imaging equipment. In the succeeding paragraphs, the semiconductor pattern may also be referred to as a calibrating pattern.

FIG. 5 illustrates an exemplary selected area 40, which depicts an image of a calibrating pattern 4 according to one embodiment of the disclosure. The calibrating pattern 4 in this embodiment includes a first pattern section and a second pattern section. Each of the first pattern section and the second pattern section includes a plurality of unit images. FIGS. 3 and 4 respectively illustrate the first pattern section 41 and the second pattern section 42 included in the calibrating pattern 4.

Further referring to FIG. 3, the first pattern section 41 includes a plurality of first unit images 411 and at least one set of second unit images 412. In the embodiment of FIG. 3, two first unit images 411 and four sets of second unit images 412 are present, but other numbers of the first unit image(s) 411 or the set(s) of second unit images 412 may be employed in other embodiments. The two first unit images 411 in the embodiment of FIG. 3 are different from each other in terms of shape, and are not aligned with each other. Therefore, it may be said that the first unit images 411 are arranged irregularly. Each of the four sets of second unit images 412 includes four rectangular second unit images 412′, and for each set 412, the second unit images 412′ are equidistantly spaced apart from one another by a distance equaling a first pitch (i.e., a distance between two adjacent second unit images 412′). The four sets of second unit images 412 are disposed to surround the first unit images 411, forming roughly a rectangular shape. In other embodiments, the sets of second unit images 412 may be disposed outside of the plurality of first unit images 411.

Further referring to FIG. 4, the second pattern section 42 includes a plurality of first unit images 421 and at least one set of second unit images 422. In the embodiment of FIG. 4, three first unit images 421 and four sets of second unit images 422 are present, but other numbers of the first unit image(s) 421 or the set(s) of second unit images 422 may be employed in other embodiments. The three first unit images 421 in the embodiment of FIG. 4 are different from one another in terms of shape, and are not aligned with one another. Therefore, it may be said that the first unit images 421 are arranged irregularly. Each of the four sets of second unit images 422 includes four rectangular second unit images 422′, and in each set 422, the second unit images 422′ are equidistantly spaced apart from one another by a distance equaling a second pitch. In this embodiment, the first pitch associated with the sets of second unit images 412 is identical to the second pitch associated with the sets of second unit images 422. The four sets of second unit images 422 are disposed to surround the first unit images 421, forming roughly a rectangular shape. In other embodiments, the sets of second unit images 422 may be disposed outside of the plurality of first unit images 421.

In the embodiment of FIG. 5, the second pattern section 42 may be superposed on the first pattern section 41 to form the calibrating pattern 4. In embodiments, the first pattern section 41 and the second pattern section 42 are images of two wiring patterns formed in different steps of a semiconductor fabrication process, and are to be arranged with respect to each other in a designated arrangement.

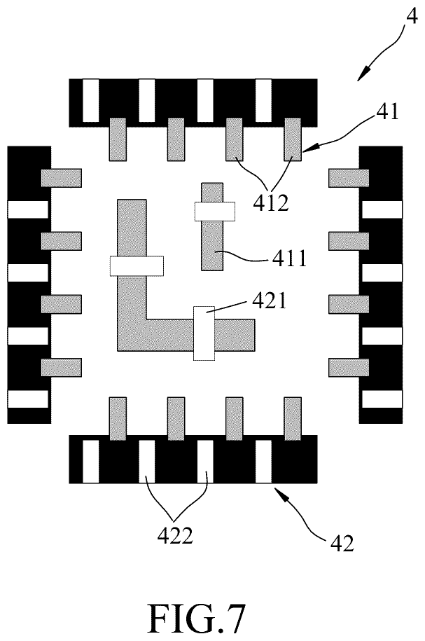

In use, the semiconductor fabrication process may involve the operations of: forming a substrate using a supporting material (e.g., a semiconductor material, a glass material, a metal material, a dielectric material, or an insulating material); and using a first sub-process to form the first pattern section 41 on the substrate and using a second sub-process to form the second pattern section 42 on the substrate, thereby forming the calibrating pattern 4 on the substrate. Each of the first sub-process and the second sub-process may be a patterning process, a photolithographic process, etc. In this embodiment, the first pattern section 41 and the second pattern section 42 may be in the form of wiring patterns, and in other embodiments, each of the first pattern section 41 and the second pattern section 42 may be in the form of trenches, vias (e.g., through holes), etc. FIG. 7 illustrates an exemplary calibrating pattern 4 according to one embodiment of the disclosure, in which the first pattern section 41 is formed on the substrate as wirings, and the second pattern section 42 is formed on the substrate as trenches. In embodiments, the first pattern section 41 and the second pattern section 42 are formed on a same layer using different processes, but may be formed on two overlaying layers in a same semiconductor device in other embodiments.

In the embodiment of FIG. 5, the first unit images 411 of the first pattern section 41 and the first unit images 421 of the second pattern section 42 cooperatively form an inner part 5, and the sets of second unit images 412 of the first pattern section 41 and the sets of second unit images 422 of the second pattern section 42 cooperatively form an outer part 6. The outer part 6 has roughly the shape of a four-sided polygon (e.g., a rectangle) to surround the inner part 5, and each side of the polygon is formed by one set of second unit images 412 and a corresponding set of second unit images 422. For each side of the outer part 6, a shape of the unit images 412′ included in the one set of second unit images 412 and a shape of the unit images 422′ included in the corresponding set of second unit images 422 are identical, and an arrangement of the unit images 412′, 422′ may be in the manner as shown in FIG. 5.

For example, in the example of FIG. 5, on a right side 61 of the outer part 6 (including one set of second unit images 412 and the corresponding set of second unit images 422), in a first direction (indicated by the arrow Y), the rectangular unit images 412′ 412′ and the second unit images 422′ are alternatively arranged, and a distance P between two adjacent rectangular unit images 412, 422′ are identical. Additionally, due to the difference between the placements of the sets of second unit images 412 and the sets of second unit images 422, on each side of the outer part 6, the second unit images 412′ and the second unit images 422′ are not perfectly aligned. For example, in the example of FIG. 5, on the right side 61 of the outer part 6, the second unit images 412′ and the second unit images 422′ are not aligned in the first direction (indicated by the arrow Y). In some embodiments, other shapes may be employed for the unit images 412′, 422′ of the sets of second unit images 412, 422, and for each side of the outer part 6, at least one edge of one of the image units 412′, 422′ included in one of the set of second image units 412 and the corresponding set of second image units 422 is parallel to a corresponding edge of one of the image units 412′, 422′ included in the other one of the set of second image units 412 and the corresponding set of second image units 422.

It is noted that while the embodiment of FIG. 5 illustrates one exemplary shape/form of the calibrating pattern 4, other shapes/forms of the calibrating pattern 4 may be employed in other embodiments.

The alignment checking unit 22 may include, but not limited to, one or more of a single core processor, a multi-core processor, a dual-core mobile processor, a microprocessor, a microcontroller, a digital signal processor (DSP), a field-programmable gate array (FPGA), an application specific integrated circuit (ASIC), a radio-frequency integrated circuit (RFIC), etc. The alignment checking unit 22 may execute a software application to perform the operations as described below.

In use, the alignment checking unit 22 is configured to obtain an overlay error dataset based on the calibrating pattern 4 in the selected area 40 and a reference dataset. Specifically, in some embodiments, the reference dataset includes a reference image corresponding with the calibrating pattern 4, indicating the relative locations of elements of the calibrating pattern 4 in an “ideal” situation where no undesired effects occurred and the inner part 5 and the outer part 6 are accurately placed. The reference image may be an image pre-generated by operating the GDS, MEBES, OASIS or other applicable systems, an image of a pattern that is formed on another substrate using an image pre-generated by operating the GDS, MEBES, OASIS or other applicable system, an image of a pattern that is formed using a patterning process, a simulated image of the calibrating pattern 4 that is to be formed on another substrate, or an image of a photomask corresponding with the calibrating pattern 4. In some embodiments, the reference image may be in a form of a data file in a data stream format for data exchange, such as a GDSII file, an OASIS file, an MEBES file, etc. In other embodiments, the reference dataset may include a plurality of reference parameters associated with the calibrating pattern 4 such as one or more of: a plurality of critical dimensions (CDs) associated with the calibrating pattern 4; a plurality of areas associated with the calibrating pattern 4; a plurality of edge placement errors (EPEs) associated with the calibrating pattern 4; and a plurality of curvatures of edges associated with the calibrating pattern 4. In some embodiments, each of the reference parameters is represented in the form of a default value.

In use, the alignment checking unit 22 may superpose the reference image onto the calibrating pattern 4, so as to determine a difference between the reference image and the calibrating pattern 4.

In one embodiment of FIG. 6, an exemplary reference image 7 (shown in dashed lines) is superposed on the calibrating pattern 4. In this embodiment, the reference image 7 includes a reference pattern 70 that has an inner part 71 and an outer part 72 that correspond with the inner part 5 and the outer part 6 of the calibrating pattern 4, respectively. Each of the inner part 71 and the outer part 72 includes a plurality of unit patterns. In use, the alignment checking unit 22 may attempt to align the outer part 72 of the reference pattern 70 with the outer part 6 of the calibrating pattern 4.

The overlay error dataset may include one or more of: differences in CDs between unit images of the calibrating pattern 4 and the unit patterns of the reference pattern 70; differences in areas between the unit images of the calibrating pattern 4 and the unit patterns of the reference pattern 70; position shifts between the unit images of the calibrating pattern 4 and the unit patterns of the reference pattern 70; and values of edge placement errors. It is noted that the components of the overlay error dataset may be obtained by the alignment checking unit 22 examining a result of the superposition of the reference pattern 70 on the calibrating pattern 4. In other embodiments where the reference image 7 is not employed, the alignment checking unit 22 may obtain pattern parameters (e.g., CDs, areas, EPEs and/or curvatures of edges) associated with the calibrating pattern 4, and compare the obtained pattern parameters with the default values of the reference parameters of the reference dataset to generate the overlay error dataset. It is noted that the operations associated with calculating CDs, areas, EPEs and/or curvatures of edges associated with the calibrating pattern 4 are well known in the related art, so details thereof are omitted herein for the sake of brevity.

The computing unit 23 is connected to the alignment checking unit 22, and may include, components that are similar to that of the alignment checking unit 22. The computing unit 23 may execute a software application to perform the operations as described below.

In use, the computing unit 23 is configured to, based on the overlay error dataset generated by the alignment checking unit 22, generate a calibrating parameter dataset that indicates one or more changes to be made on one or more process parameters that are to be used in the semiconductor fabrication process. The process parameters may include a film stress, a thermal expansion coefficient, etc.

In practice, during a current semiconductor fabrication process, in which the calibrating pattern 4 is formed on the substrate via the first sub-process and the second sub-process, each of the process parameters may be set as a current value (e.g., a default value). In the case where the resulting calibrating pattern 4 is deemed to have overlay errors with respect to the reference dataset, it may be deduced that one or more of the process parameters may need to be adjusted from the current value, so as to ensure that the semiconductor fabrication process applying the adjusted process parameters for manufacturing a next batch of semiconductor devices may result in a calibrating pattern 4 without overlay errors.

After the calibrating parameter dataset is calculated, the calibrating parameter dataset may be utilized by the system 20 for the semiconductor fabrication process for the next batch (e.g., the process parameters for one or both of the first sub-process and the second sub-process may be adjusted). Alternatively, referring to FIG. 1, the calibrating parameter dataset may be transmitted to an external system 10 (which may be embodied using MEBES or other applicable systems) so as to enable the external system 10 to generate one or more photomasks based on the calibrating parameter dataset. As such, the generated photomask(s) may be used for one or both of the first sub-process and the second sub-process in the semiconductor fabrication process for the next batch.

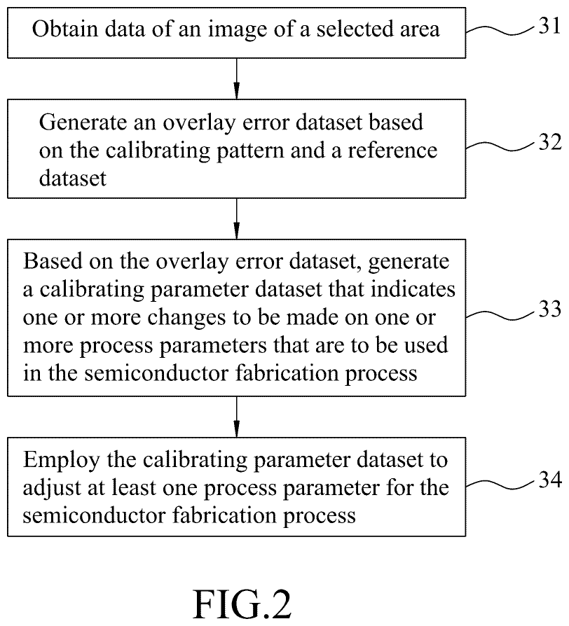

FIG. 2 is a flow chart illustrating steps of a method for overlay control according to one embodiment of the disclosure. In this embodiment, the method is implemented using the system 20 as shown in FIG. 1.

In step 31, the data obtaining unit 21 obtains data of an image of the selected area 40. In some embodiments, the selected area 40 is selected from the substrate, and includes the calibrating pattern 4 as shown in FIG. 5.

In step 32, the alignment checking unit 22 generates an overlay error dataset based on the calibrating pattern 4 and a reference dataset. In this embodiment, the reference dataset includes a reference image 7 that has a reference pattern 70. The reference pattern 70 has an inner part 71 and an outer part 72 that correspond with the inner part 5 and the outer part 6 of the calibrating pattern 4, respectively. Each of the inner part 71 and the outer part 72 includes a plurality of unit patterns. In some embodiments, the alignment checking unit 22 may align the outer part 72 of the reference pattern 70 with the outer part 6 of the calibrating pattern 4. Then, for each of the unit images of the calibrating pattern 4 that is not aligned with the corresponding one of the unit patterns of the reference pattern 70 and/or that has a shape or CDs that differ from the corresponding one of the unit patterns of the reference pattern 70, the difference may be identified and used to generate the overlay error dataset.

Alternatively, in some embodiments, the operations of step 32 may be done separately with respect to the first pattern section 41 and the second pattern section 42. For example, the alignment checking unit 22 may align those of the unit patterns of the reference pattern 70 that correspond with one of the first pattern section 41 (e.g., the set(s) of second unit images 412) and the second pattern section 42 (e.g., the set(s) of second unit images 422), respectively with the unit images of the one of the first pattern section 41 and the second pattern section 42. Then, a partial overlay error dataset associated with the one of the first pattern section 41 and the second pattern section 42 may be generated to serve as the overlay error dataset. In some cases, after the partial overlay error dataset is generated, the alignment checking unit 22 may proceed to generate another partial overlay error dataset with respect to the other one of the first pattern section 41 and the second pattern section 42, and the two partial overlay error dataset cooperatively serve as the overlay error dataset.

Then, in step 33, based on the overlay error dataset generated by the alignment checking unit 22, the computing unit 23 generates a calibrating parameter dataset that indicates one or more changes to be made on one or more process parameters that are to be used in the semiconductor fabrication process.

Then, in step 34, the system 20 employs the calibrating parameter dataset to adjust at least one process parameter for the semiconductor fabrication process that includes the first sub-process and the second sub-process for manufacturing a next batch of semiconductor devices; that is, the process parameter(s) for one or both of the first sub-process and the second sub-process may be adjusted. Afterward, the at least one process parameter thus adjusted may be applied to the semiconductor fabrication process. Alternatively, the calibrating parameter dataset may be transmitted to an external system 10 (which may be embodied using MEBES or other applicable systems) so as to enable the external system 10 to generate one or more photomasks based on the calibrating parameter dataset. As such, the generated photomask(s) may be used for one or both of the first sub-process and the second sub-process in the semiconductor fabrication process for the next batch.

In some alternative embodiments, in step 32, the alignment checking unit 22 may be configured to determine, with respect to each of the unit images of the calibrating pattern 4, a relative displacement between a location of the unit image and an expected location of the unit image based on the reference dataset, and generate the overlay error dataset based on the relative displacements of the unit images. In the embodiment of FIG. 6, the expected location for each of the unit images may be indicated by the corresponding one of the unit patterns of the reference pattern 70 of the reference image 7 (shown in dashed lines).

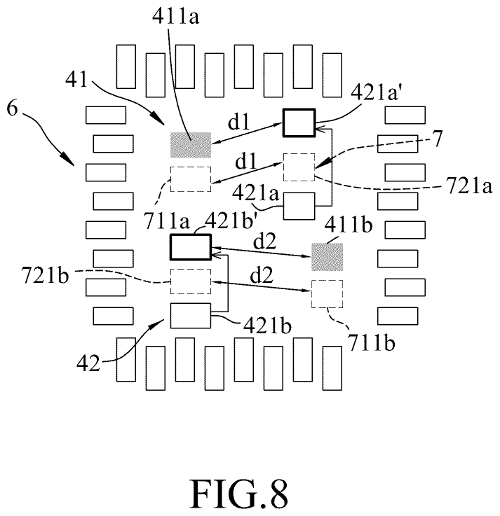

FIG. 8 illustrates an alternative manner in which the relative displacements for the unit images are obtained. In this embodiment, the first pattern section 41 includes two first unit images 411a and 411b, the second pattern section 42 includes two first unit images 421a and 421b, and the reference image 7 includes unit images 711a, 711b, 721a and 721b (indicated by blocks with dashed lines). Each of the first pattern section 41 and the second pattern section 42 may include a same number of first unit images, and therefore the first unit images from the first pattern section 41 and the second pattern section 42 may be “paired” and have a specific spatial relationship. For the pair of unit images 711a and 721a, a specific spatial relationship may be pre-defined, and the same goes for the pair of unit images 711b and 721b, as indicated by the double ended arrows in FIG. 8. That is to say, in a desired situation, the first unit image 411a and the corresponding first unit image 421a that form a pair should have a spatial relationship as indicated by the double ended arrow d1, and the first unit image 411b and the corresponding first unit image 421b that form another pair should have a spatial relationship as indicated by the double ended arrow d2.

In use, when implementing step 32, the alignment checking unit 22 determines, with respect to each of the unit images included in the first pattern section 41 and the second pattern section 42, a relative displacement between a location of the unit image and an expected location of the unit image based on the reference dataset. For example, in the embodiment of FIG. 8, the first pattern section 41 (indicated by the dark blocks) may be selected as a reference section, and for each of the unit images of the first pattern section 41, a corresponding one of the unit images of the second pattern section 42 is examined.

Specifically, a location of the first unit image 411a serves as a reference point, and an expected location of the unit image 421a is determined by the specific spatial relationship indicated by the arrow d1. As a result, the expected location of the unit image 421a is indicated by the block 421a′. It is noted that while both the first unit image 411a and the first unit image 421a actually deviate from the locations as indicated by the reference image 7 (i.e., expected locations), in this example, the alignment checking unit 22 only determines in step 32 that the location of the first unit image 421a has deviated from its expected location, but does not determine that the location of the first unit image 411a has deviated from its expected location.

Similarly, a location of the first unit image 411b serves as a reference point, and an expected location of the unit image 421b is determined by the specific spatial relationship indicated by the arrow d2. As a result, the expected location of the unit image 421b is indicated by the block 421b′. In the above manner, two relative displacements (from 421a to 421a′ (or vice versa) and from 421b to 421b′ (or vice versa)) may be used to generate the overlay error dataset.

Then, in step 33, the computing unit 23, based on the overlay error dataset generated by the alignment checking unit 22, generates a calibrating parameter dataset that indicates one or more changes to be made on one or more process parameters that are to be used in the semiconductor fabrication process of a next batch of semiconductor devices, so as to ensure the spatial relationship between each pair of unit images in the semiconductor device of the next batch manufactured by the semiconductor fabrication process.

It is noted that in other examples, the second pattern section 42 (indicated by the blank blocks with solid lines) may be selected as a reference section, and for each unit image of the second pattern section 42, a corresponding unit image of the first pattern section 41 is examined in the manner as described above.

In some embodiments, the operations for step 32 includes, for each of the unit images included in the first pattern section 41 and the second pattern section 42, determining the expected location as indicated by the reference image 7. That is to say, four relative displacements (411a to 711a, 411b to 711b, 421a to 721a and 421b to 721b) may be used to generate the overlay error dataset. In some embodiments, the operations for step 32 includes, for each of the unit images included in one of the first pattern section 41 and the second pattern section 42, determining the expected location indicated by the reference image 7, and calculating a relative displacement. That is to say, four relative displacements (from 411a to 711a (or vice versa), from 411b to 711b (or vice versa), from 421a to 721a (or vice versa), and from 421b to 721b (or vice versa)) may be used to generate the overlay error dataset.

Then, after the calibrating parameter dataset is generated in step 33, the calibrating parameter dataset is transmitted to the external system 10 (which may be embodied using MEBES or other applicable systems) so as to enable the external system 10 to generate one or more photomasks based on the calibrating parameter dataset in step 34.

In brief, embodiments of the disclosure provide a calibrating pattern 4 that includes an outer part 6 (including sets of second unit images 412 included in a first pattern section 41 and sets of second unit images 422 included in a second pattern section 42) and an inner part 5 (including first unit images 411 included in the first pattern section 41 and first unit images 421 included in the second pattern section 42). While the unit images of the outer part 6 are arranged in a more regular manner (i.e., for each side of the outer part 6, adjacent unit images are equidistantly spaced apart, and the unit images roughly form a rectangle), the unit images of the inner part 5 are arranged in an irregular manner. In embodiments, the first pattern section 41 and the second pattern section 42 may be formed on a substrate in two separate sub-processes, and an overlay error may be determined with respect the outer part 6 and/or the inner part 5. As such, the calibrating pattern 4 according to embodiments of the disclosure provides a way to implement a more accurate way of assisting in overlay control.

Additionally, embodiments of the disclosure provide a method and a system for overlay control. In embodiments, the first pattern section 41 and the second pattern section 42 may be employed. Specifically, in some examples, the reference dataset includes a reference image 7 that has an inner part 71 and an outer part 72 that correspond with the inner part 5 and the outer part 6 of the calibrating pattern 4, respectively. Each of the inner part 71 and the outer part 72 includes a plurality of unit patterns to correspond with the unit images of the respective one of the first pattern section 41 and the second pattern section 42. In use, the system may determine, with respect to each of the unit images included in the first pattern section 41 and/or the second pattern section 42, a relative displacement between an actual location of the unit image and an expected location of the unit image based on the reference image 7. As such, for each of the unit images included in the first pattern section 41 and/or the second pattern section 42, a relative displacement is determined, and one or more process parameters may be adjusted for the manufacturing process of a next batch of semiconductor devices. Using the method and the system as described in the disclosure, a more accurate way of assisting in overlay control may be implemented.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A semiconductor pattern used for a semiconductor fabrication process, comprising:
a first pattern section including a plurality of first unit images and at least one set of second unit images, the plurality of first unit images being disposed irregularly, the at least one set of second unit images being disposed outside of the plurality of first unit images, each of the at least one set of second unit images including a plurality of second unit images that are equidistantly spaced apart from one another by a distance equaling a first pitch; and
a second pattern section including a plurality of first unit images and at least one set of second unit images, the plurality of first unit images being disposed irregularly, the at least one set of second unit images being disposed outside of the plurality of first unit images, each of the at least one set of second unit images including a plurality of second unit images that are equidistantly spaced apart from one another by a distance equaling a second pitch, the first pitch being identical to the second pitch;
wherein:
the first pattern section and the second pattern section are to be formed on a substrate using a first sub-process and a second sub-process of the semiconductor fabrication process, respectively;
the first unit images of the first pattern section and the first unit images of the second pattern section cooperatively form an inner part, and the at least one set of second unit images of the first pattern section and the at least one set of second unit images of the second pattern section cooperatively form an outer part;
the outer part has at least one side, each of which is formed by one of the at least one set of second unit images of the first pattern section and a corresponding one of the at least one set of second unit images of the second pattern section.

2. The semiconductor pattern as claimed in claim 1, wherein the first unit images and the at least one set of second unit images of each of the first pattern section and the second pattern section are to be formed on a substrate as wirings, trenches, and/or a through holes.

3. The semiconductor pattern as claimed in claim 1, wherein the outer part has four sides and has a rectangular shape to surround the inner part.

4. The semiconductor pattern as claimed in claim 3, wherein, for each of the four sides, the second unit images of the first pattern section and the second unit images of the second pattern section are alternatively arranged, and a distance between two adjacent second unit images are identical.

5. The semiconductor pattern as claimed in claim 4, wherein, for each of the four sides of the outer part:
shapes of the second unit images of the first pattern section and shapes of the second unit images of the second pattern section are identical; and
at least one edge of one of the second unit images included in one of the first pattern section and the second pattern section is parallel to a corresponding edge of one of the second unit images included in the other one of the first pattern section and the second pattern section.

6. The semiconductor pattern as claimed in claim 1, wherein the substrate is formed using one of: a semiconductor material, a glass material, a metal material, a dielectric material, and an insulating material.

7. A method for overlay control, comprising:
obtaining data of an image of a selected area that includes the semiconductor pattern as claimed in claim 1;
generating an overlay error dataset based on the semiconductor pattern and a reference dataset, the reference dataset including a reference image that corresponds with the semiconductor pattern, or a plurality of reference parameters associated with the semiconductor pattern; and
generating, based on the overlay error dataset, a calibrating parameter dataset that indicates one or more changes to be made on at least one process parameter that is to be used in the semiconductor fabrication process for manufacturing a next batch of semiconductor devices.

8. The method of claim 7, further comprising employing the calibrating parameter dataset to adjust the at least one process parameter for the semiconductor fabrication process that includes the first sub-process and the second sub-process.

9. The method of claim 8, further comprising applying the at least one process parameter thus adjusted to the semiconductor fabrication process for the next batch.

10. The method of claim 9, wherein the semiconductor fabrication process involves generating one or more photomasks to be used in one or both of the first sub-process and the second sub-process.

11. The method of claim 7, wherein generating the overlay error dataset includes:
determining, with respect to each of the unit images of the first pattern section and the second pattern section, a relative displacement between an actual location of the unit image and an expected location of the unit image based on the reference dataset, and generating the overlay error dataset using the relative displacements of the unit images;
wherein the reference dataset includes, for each of the unit images of the first pattern section, a pre-defined spatial relationship with a corresponding one of the unit images of the second pattern section, and with respect to each of the unit images of the first pattern section, the expected location of the unit image is obtained using the corresponding pre-defined spatial relationship.

12. The method of claim 7, wherein generating the overlay error dataset includes:
determining, with respect to each of the unit images of one of the first pattern section and the second pattern section, a relative displacement between an actual location of the unit image and an expected location of the unit image based on the reference dataset, and generating the overlay error dataset using the relative displacements thus determined for the unit images of said one of the first pattern section and the second pattern section.

13. The method of claim 7, wherein the reference dataset includes a reference image that is one of:
an image pre-generated by operating one of a graphic data system (GDS), a manufacturing electron beam exposure system (MEBES), an open artwork system interchange system (OASIS) program or other applicable systems;
an image of a pattern formed on another substrate using the image pre-generated by operating the GDS, MEBES, OASIS or other applicable systems;
an image of a pattern that is formed using a patterning process;
a simulated image of the semiconductor pattern that is to be formed on another substrate; and
an image of a photomask corresponding with the semiconductor pattern.

14. The method of claim 7, wherein:
the reference dataset includes a plurality of reference parameters associated with the semiconductor pattern, the reference parameters include one or more of: a plurality of critical dimensions (CDs) associated with the semiconductor pattern; a plurality of areas associated with the semiconductor pattern; a plurality of edge placement errors (EPEs) associated with the semiconductor pattern; and a plurality of curvatures of edges associated with the semiconductor pattern; and
the overlay error dataset is generated by obtaining the reference parameters associated with the semiconductor pattern, and comparing pattern parameters that are associated with the semiconductor pattern with the reference parameters included in the reference dataset to obtain the overlay error dataset.

15. The method of claim 14, wherein the calibrating parameter dataset is generated based on a difference between the semiconductor pattern and the reference dataset, with respect to one or both of the first pattern section and the second pattern section.

16. A system for overlay control, comprising:
a data obtaining unit that obtains data of an image of a selected area that includes the semiconductor pattern as claimed in claim 1;
an alignment checking unit that generates an overlay error dataset based on the semiconductor pattern and a reference dataset; and
a computing unit that generates, based on the overlay error dataset, a calibrating parameter dataset that indicates one or more changes to be made on at least one process parameter that is to be used in the semiconductor fabrication process for manufacturing a next batch of semiconductor devices.

17. The system of claim 16, wherein the reference dataset includes a reference image corresponding with the semiconductor pattern, or a plurality of reference parameters associated with the semiconductor pattern.

18. The system of claim 16, wherein:
the alignment checking unit generates the overlay error dataset by determining, with respect to each of the unit images of the first pattern section and the second pattern section, a relative displacement between an actual location of the unit image and an expected location of the unit image based on the reference dataset, and generating the overlay error dataset using the relative displacements of the unit images; and
wherein the reference dataset includes, for each of the unit images of the first pattern section, a pre-defined spatial relationship with a corresponding one of the unit images of the second pattern section, and, with respect to each of the unit images of the first pattern section, the expected location of the unit image is obtained using the corresponding pre-defined spatial relationship.

19. The system of claim 18, wherein the semiconductor fabrication process involves generating one or more photomasks to be used in one or both of the first sub-process and the second sub-process.

20. The system of claim 16, wherein the reference dataset includes a reference image that is one of:
an image pre-generated by operating one of a graphic data system (GDS), a manufacturing electron beam exposure system (MEBES), an open artwork system interchange system (OASIS) program or other applicable systems;
an image of a pattern formed on another substrate using the image pre-generated by operating the GDS, MEBES, OASIS or other applicable systems;
an image of a pattern that is formed using a patterning process;
a simulated image of the semiconductor pattern that is to be formed on another substrate; and
an image of a photomask corresponding with the semiconductor pattern.

21. The system of claim 16, wherein:
the reference dataset includes a plurality of reference parameters associated with the semiconductor pattern, the reference parameters include one or more of: a plurality of critical dimensions (CDs) associated with the semiconductor pattern; a plurality of areas associated with the semiconductor pattern; a plurality of edge placement errors (EPEs) associated with the semiconductor pattern; and a plurality of curvatures of edges associated with the semiconductor pattern; and
the overlay error dataset is generated by obtaining the reference parameters associated with the semiconductor pattern, and comparing pattern parameters that are associated with the semiconductor pattern with the reference parameters included in the reference dataset to obtain the overlay error dataset.

22. The system of claim 16, wherein the calibrating parameter dataset is generated based on a difference between the semiconductor pattern and the reference dataset, with respect to one or both of the first pattern section and the second pattern section.
